(19) United States
(12) Patent Application Publication
(10) Pub. No.: US 2026/0134179 A1
(43) Pub. Date: May 14, 2026

(54) INTEGRATED HYDRODYNAMIC AND WATER QUALITY SIMULATION METHOD FOR WATER SUPPLY SYSTEMS OF WATER TREATMENT PLANTS, PIPE NETWORKS, AND RIVERS

(71) Applicant: Tsinghua Shenzhen International Graduate School, Shenzhen (CN)

(72) Inventors: Manjie LI, Shenzhen (CN); Zhi Wang, Shenzhen (CN)

(73) Assignee: Tsinghua Shenzhen International Graduate School, Shenzhen (CN)

(21) Appl. No.: 19/445,647

(22) Filed: Jan. 12, 2026

Related U.S. Application Data
(63) Continuation of application No. PCT/CN2024/128329, filed on Oct. 30, 2024.

(30) Foreign Application Priority Data
Jul. 12, 2024 (CN) 202410931458.2

(51) Int. Cl. G06F 30/28

(52) U.S. Cl. CPC G06F 30/28

(57) ABSTRACT

An integrated hydrodynamic and water quality simulation method for water supply systems of water treatment plants, pipe networks, and rivers includes steps of river water source simulation, dynamic analysis of water quality at the water intake, construction of a water supply pipe network water quality prediction model, data interface development, one-dimensional pipe network hydrodynamic and water quality simulation, and integrated model integration and automation. The method can utilize open-source software, and through automated scripts and data interfaces, realize the continuous simulation and real-time update of water quality and hydrodynamic parameters from rivers to water supply pipe networks. The model integrates treatment effect of water treatment plants, which are simplified as treatment nodes in the pipeline system, ensuring the authenticity and accuracy of simulation results. This method is not only easy to operate and implement, but also can automatically generate time-series graphs of water quality parameters, significantly improving simulation efficiency.

### CROSS REFERENCE TO RELATED APPLICATIONS

This application is a continuation application of PCT Application No. PCT/CN2024/128329, filed on Oct. 30th, 2024. The content of the application is incorporated herein by reference.

### BACKGROUND OF THE INVENTION

### 1. Field of the Invention

The present invention relates to hydrodynamic and water quality simulation technology for water supply pipe networks, and more particularly to an integrated hydrodynamic and water quality simulation method for water supply systems of water treatment plants, pipe networks, and rivers.

### 2. Description of the Prior Art

In the field of hydrodynamic and water quality simulation for water sources, classic software includes HEC-RAS: developed by the Hydrologic Engineering Center of the U.S. Army Corps of Engineers, it features complete one-dimensional and two-dimensional coupled hydrodynamic and water environment simulation capabilities, and can simulate hydraulic structures such as sluices, culverts, bridges, and pumping stations. In addition, MIKE is a widely used software for simulating hydrodynamics, water quality, sediment, and ecology in estuaries, rivers, and lakes, covering one-dimensional, two-dimensional, and three-dimensional scenarios. There is also Delft3D: a three-dimensional hydrodynamic-water quality model system that includes modules for water flow, hydrodynamics, waves, sediment, water quality, and ecology, with online dynamic coupling between each module. WASP6 and WASP7: developed by the U.S. Environmental Protection Agency, the WASP model is a comprehensive water quality simulation model capable of simulating water quality changes in rivers, reservoirs, and lakes. However, these model methods have more or less drawbacks, such as slow calculation speed and some closed-source programs, which are not conducive to secondary development.

In terms of water quality simulation for water supply pipe networks, EPANET is an open-source software widely used to simulate the hydraulic and water quality characteristics of water supply pipe networks. Some researchers have accurately simulated chlorine residual changes in actual pipe networks using the chlorine residual decay kinetic model based on EPANET. EPANET and EPANET-MSX have also been proven to be important tools in water supply pipe network adjustment calculations and multi-source water supply (rivers, reservoirs, wells, etc.) problems. Building on EPANET, EPANET-MSX adds multi-species water quality simulation functionality, enabling the analysis of more complex biochemical reactions in pipe networks, such as the oxidation of heavy metals in pipe networks and adsorption processes on pipe walls; the chlorine residual decay model combined with relevant optimization algorithms can be used to select locations for secondary chlorination and pressure boosting points.

Currently, there are few studies on the simulation of the entire water intake and supply process, while the demand for integrated water supply quality prediction models is increasingly strong.

It should be noted that the information disclosed in the above background section is only for understanding the background of the present application and may include information that does not constitute the prior art known to those of ordinary skill in the art.

### SUMMARY OF THE INVENTION

The main objective of the present invention is to overcome the defects in the aforementioned background art and provide an integrated hydrodynamic and water quality simulation method for water supply systems of water treatment plants, pipe networks, and rivers.

To achieve the above objective, the present invention adopts the following technical solution:
An integrated hydrodynamic and water quality simulation method for water supply systems of water treatment plants, pipe networks, and rivers, comprising the following steps:

S1. River water source simulation: Combine collected river topographic data and river shoreline data to construct a two-dimensional (2D) river hydrodynamic and water quality model. This model is configured with boundary hydrodynamic and water quality parameters to simulate the hydrodynamic and water quality conditions of the river water source.

S2. Dynamic analysis of water quality at the water intake: Monitor and analyze the temporal variation of water quality parameters at the water intake using the 2D river hydrodynamic and water quality model, so as to provide key data for dynamic water quality assessment.

S3. Construction of a water supply pipe network water quality prediction model: Construct a water supply pipe network water quality prediction model that integrates multi-water source inputs. The water treatment plant is simplified as a treatment node in the pipeline system to simulate its water quality treatment effects, including the removal efficiency of targeted pollutants.

S4. Data interface development: Establish a data interface to realize data exchange and synchronization between the 2D river hydrodynamic and water quality model and the water supply pipe network water quality prediction model, ensuring the consistency and continuity of data between the models.

S5. One-dimensional (1D) pipe network hydrodynamic and water quality simulation: Based on the data obtained from the 2D river hydrodynamic and water quality model, the water supply pipe network water quality prediction model performs 1D hydrodynamic and water quality simulation of the water supply pipe network. Among them, the water quality and hydrodynamic parameters provided by the 2D river hydrodynamic and water quality model are input into the water supply pipe network water quality prediction model as boundary conditions or initial conditions to predict the water quality changes and hydraulic behaviors in the water supply pipe network.

S6. Integrated model integration and automation: Integrate the river hydrodynamic and water quality model and the water supply pipe network water quality prediction model into a complete numerical model for the integrated water supply system of water treatment plants, pipe networks, and rivers, so as to automate the entire water quality change simulation process.

In some optional implementations, in step S1, the OpenFOAM software is used to construct the 2D river hydrodynamic and water quality model; in step S2, the Probe function of OpenFOAM is used to monitor the changes of water quality parameters at the water intake and obtain the temporal variation data of the water quality parameters.

In some optional implementations, step S2 specifically includes:

S2.1. Establish a geometric model of the river shoreline and export it in a format suitable for mesh generation software.

S2.2. According to the characteristics of the river, use mesh generation software to draw a 2D mesh adapted to the river morphology, and output it in a format suitable for the Computational Fluid Dynamics (CFD) software OpenFOAM.

S2.3. Convert the exported mesh file into a format recognizable by OpenFOAM software, and store it as a standard mesh file in the case folder.

S2.4. Set the properties of the mesh in OpenFOAM software. For 2D simulation, specify the upper and lower boundary conditions and set the dimension in the vertical direction.

S2.5. Use the built-in tools of OpenFOAM software to extract the coordinate data of the mesh centers.

S2.6. Perform topographic data interpolation: combine the topographic data with the mesh data, use interpolation technology to obtain the topographic depth information at the mesh centers, and export the data.

S2.7. Integrate the interpolated topographic data into the OpenFOAM model to provide accurate topographic conditions for the simulation.

S2.8. Define model parameters: set the simulation parameters of OpenFOAM software, including time step, total simulation time, physical model settings, boundary conditions, as well as the diffusion and attenuation characteristics of pollutants.

S2.9. Set monitoring points in OpenFOAM software to track and record the temporal changes of water quality parameters at specific locations.

In some optional implementations, in step S3, the EPANET-MSX software is used to establish the water supply pipe network water quality prediction model based on the collected data of pipe network topology, pipe segment characteristics, node characteristics, and boundary conditions.

In some optional implementations, step S3 specifically includes:

S3.1. Collect data such as the topology of the water supply pipe network, pipe segment characteristics, node characteristics, and boundary conditions.

S3.2. Create point objects and line objects in the water supply pipe network. The point objects include nodes, reservoirs, and water tanks, while the line objects include pipe segments, valves, and pumps.

S3.3. Define attribute fields for the point objects and line objects respectively, including but not limited to node number, coordinates, elevation, water demand, reservoir number, total head, water tank size, pipe segment specification, valve type, and pump performance.

S3.4. Set parameters such as the simulation time step and total duration to provide time control for the simulation process.

S3.5. Define the hydrodynamic conditions of the pipe network, including pressure, flow rate, and water head, and ensure that the hydrodynamic states of all nodes and pipe segments are set correctly.

S3.6. Add corresponding chemical species according to the simulation requirements, and set their chemical properties and kinetic parameters.

S3.7. Configure the initial state of the pipe network, including the initial concentration of water quality components and flow velocity, to prepare for the simulation calculation.

S3.8. Simulate the water treatment plant process by adding a Source module to the model.

In some optional implementations, in step S4, a data interface is constructed by writing Python scripts to realize data exchange between OpenFOAM software and EPANET-MSX software, and convert the water quality and hydrodynamic parameters output by OpenFOAM into the input format required by EPANET-MSX software.

In some optional implementations, step S4 specifically includes:

S4.1. Determine the storage path of the CSV file (recording the temporal variation of water quality parameters at the water intake) exported by the probe function of OpenFOAM software.

S4.2. Develop a Python function to read water quality parameter data (including water quality concentration data) from OpenFOAM software.

S4.3. Convert the read water quality concentration data into relative coefficients, and realize standardization by dividing each value in the concentration column by the first value of the column.

S4.4. Determine the storage path of the input file of EPANET-MSX software.

S4.5. Use Python code to automatically update the calculated relative coefficients to the PATTERNS section in the EPANET-MSX model file.

S4.6. In the EPANET-MSX model file, replace the original time pattern with the newly calculated relative coefficients to reflect the temporal variation of water quality parameters.

In some optional implementations, step S6 specifically includes:
S6.1. Create a Python script, use the ‘subprocess’ module in the Python script to specify the path and name of the OpenFOAM case, and call the OpenFOAM solver to run the simulation;
S6.2. Run the Python data transmission interface through the Python script to realize data synchronization between different software;
S6.3. Call the EPANET-MSX library through the Python script to execute the water quality simulation of the water supply pipe network;
S6.4. Parse the water quality parameter information of specific nodes and pipe segments from the output file of EPANET-MSX;
S6.6. Convert the parsed time data into floating-point numbers in hours to meet the plotting requirements;
S6.7. Define a plotting function in Python, set the image format, and prepare for generating the time-series curve graph;
S6.8. Use the defined plotting function to generate the time-series curve graph of water quality parameters for specific nodes and pipe segments.

A computer-readable storage medium storing a computer program, where the computer program, when executed by a processor, implements the aforementioned integrated hydrodynamic and water quality simulation method for water supply systems of water treatment plants, pipe networks, and rivers.

A computer program product including a computer program, where the computer program, when executed by a processor, implements the aforementioned integrated hydrodynamic and water quality simulation method for water supply systems of water treatment plants, pipe networks, and rivers.

### Advantages of the Present Invention

The integrated hydrodynamic and water quality simulation method for water supply systems of water treatment plants, pipe networks, and rivers of the present invention can comprehensively evaluate and predict the operation status of the entire water supply system, from the water intake river and water treatment plant to the water supply pipe network, by constructing a water quality simulation model. This is of great significance for the interconnected water supply, collaborative prevention and control, and water quality safety guarantee in water network construction.

The present invention establishes a 2D river hydrodynamic and water quality model and a 1D water supply plant-network model, and realizes data exchange and synchronization between the 2D river hydrodynamic and water quality model and the water supply pipe network water quality prediction model by constructing a data interface. It simulates complex biochemical reactions in the water supply plant-network; the data exchange interface can realize real-time update of the inlet boundary conditions of the water treatment plant, and the water treatment plant is simplified as a treatment node in the pipeline system to truly reflect the hydraulic and water quality changes in the water supply pipe network.

By integrating the river hydrodynamic and water quality model and the water supply pipe network water quality prediction model into a complete numerical model for the integrated water supply system of water treatment plants, pipe networks, and rivers, the entire simulation process of water quality changes can be automated through one-click operation of the automated script and automatic plotting of result curves, forming a water quality simulation solution that is easy to apply and promote.

This method not only has high operability and secondary development potential, but also can be customized according to actual needs, enhancing the adaptability and flexibility of the model. Meanwhile, the present invention is easy to implement, can automatically generate time-series graphs of water quality parameters, simplifies the operation process, and improves the implementation efficiency.

Water supply enterprises and water conservancy departments can use the present invention to establish an information management system for water supply pipe networks, conduct long-time-series water supply quality prediction and simulation, and provide a scientific basis for the daily management and maintenance of pipe networks, enhanced disinfection of water quality, energy conservation and consumption reduction, and research on water quality stability guarantee measures under extreme disasters. It has high practical value and broad application prospects.

In a preferred embodiment, the integrated hydrodynamic and water quality simulation method for water supply systems of water treatment plants, pipe networks, and rivers of the present invention can construct an integrated model based on the open-source Computational Fluid Dynamics (CFD) software OpenFOAM, the EPANET-MSX pipe network multi-species reaction code, and a data exchange interface. This enables the overall evaluation of the water intake river-water treatment plant-water supply pipe network, and can comprehensively evaluate and predict the operation status of the entire water supply system. The constructed water quality simulation model has significant advantages such as simple structure, good performance, and low cost.

Other advantages of the embodiments of the present invention will be further described below.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic block diagram of the integrated hydrodynamic and water quality simulation method for water supply systems of water treatment plants, pipe networks, and rivers according to an embodiment of the present invention.

FIG. 2 is a spatiotemporal distribution diagram of trivalent arsenic (As³⁺) in a river simulated by OpenFOAM according to an embodiment of the present invention.

FIGS. 3a and 3b are respectively a diagram of the coordinates of the water intake and a diagram of extracting time-series water quality data according to an embodiment of the present invention.

FIG. 4 shows the construction of a water supply pipe network water quality model according to an embodiment of the present invention, as well as the oxidation and adsorption reactions of trivalent arsenic (As³⁺) in the pipe network under the action of chloride ions, involving the interaction process between the pipe wall and the flowing water source.

FIG. 5 shows the automatically generated time-series of water quality parameter changes at Node A according to an embodiment of the present invention.

FIG. 6 shows the automatically generated time-series of water quality parameter changes in Pipe Segment 1 according to an embodiment of the present invention.

### DETAILED DESCRIPTION

The following provides a detailed description of the implementation modes of the present invention. It should be emphasized that the following description is merely exemplary and is not intended to limit the scope and application of the present invention.

It should be noted that when an element is referred to as being “fixed to” or “disposed on” another element, it can be directly on the other element or indirectly on the other element. When an element is referred to as being “connected to” another element, it can be directly connected to the other element or indirectly connected to the other element. In addition, the connection can be for fixing, coupling, or communication purposes.

It should be understood that the terms “length”, “width”, “upper”, “lower”, “front”, “rear”, “left”, “right”, “vertical”, “horizontal”, “top”, “bottom”, “inner”, “outer” and other terms indicating orientations or positional relationships are based on the orientations or positional relationships shown in the accompanying drawings. They are only used to facilitate the description of the embodiments of the present invention and simplify the description, and do not indicate or imply that the device or element referred to must have a specific orientation, be constructed and operated in a specific orientation. Therefore, these terms should not be construed as limiting the present invention.

In addition, the terms “first” and “second” are only used for descriptive purposes and should not be understood as indicating or implying relative importance or implicitly indicating the number of technical features indicated. Thus, a feature defined with “first” or “second” may explicitly or implicitly include one or more such features. In the description of the embodiments of the present invention, the meaning of “plurality” is two or more, unless otherwise clearly and specifically defined.

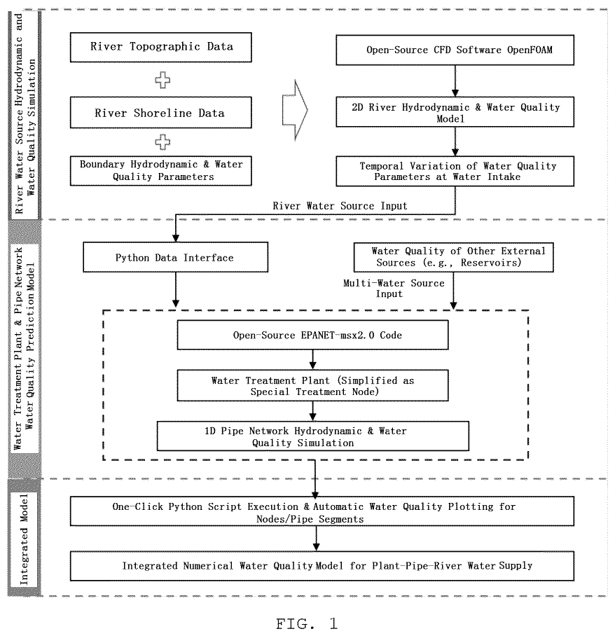

Referring to FIG. 1, an embodiment of the present invention provides an integrated hydrodynamic and water quality simulation method for water supply systems of water treatment plants, pipe networks, and rivers, which includes the following steps:

S1. River water source simulation: Combine collected river topographic data and river shoreline data to construct a two-dimensional (2D) river hydrodynamic and water quality model. This model is configured with boundary hydrodynamic and water quality parameters to simulate the hydrodynamic and water quality conditions of the river water source.

S2. Dynamic analysis of water quality at the water intake: Monitor and analyze the temporal variation of water quality parameters at the water intake using the 2D river hydrodynamic and water quality model, so as to provide key data for dynamic water quality assessment.

S3. Construction of a water supply pipe network water quality prediction model: Construct a water supply pipe network water quality prediction model that integrates multi-water source inputs. The water treatment plant is simplified as a treatment node in the pipeline system to simulate its water quality treatment effects, including the removal efficiency of targeted pollutants.

S4. Data interface development: Establish a data interface to realize data exchange and synchronization between the 2D river hydrodynamic and water quality model and the water supply pipe network water quality prediction model, ensuring the consistency and continuity of data between the models.

S5. One-dimensional (1D) pipe network hydrodynamic and water quality simulation: Based on the data obtained from the 2D river hydrodynamic and water quality model, the water supply pipe network water quality prediction model performs 1D hydrodynamic and water quality simulation of the water supply pipe network. Among them, the water quality and hydrodynamic parameters provided by the 2D river hydrodynamic and water quality model are input into the water supply pipe network water quality prediction model as boundary conditions or initial conditions to predict the water quality changes and hydraulic behaviors in the water supply pipe network.

S6. Integrated model integration and automation: Integrate the river hydrodynamic and water quality model and the water supply pipe network water quality prediction model into a complete numerical model for the integrated water supply system of water treatment plants, pipe networks, and rivers, so as to automate the entire water quality change simulation process.

The integrated hydrodynamic and water quality simulation method for water supply systems of water treatment plants, pipe networks, and rivers in the preferred embodiment of the present invention can be constructed based on the open-source Computational Fluid Dynamics (CFD) software OpenFOAM and the EPANET-MSX pipe network multi-species reaction code. It enables the overall evaluation of the water intake river-water treatment plant-water supply pipe network, and can comprehensively evaluate and predict the operation status of the entire water supply system. The model has advantages such as a simple structure, good performance, and low cost.

The embodiment of the present invention realizes the integrated water quality simulation of the water supply system of water treatment plants, pipe networks, and rivers, that is, integrating water treatment plants, water supply pipe networks, and natural rivers into a unified framework. This can comprehensively evaluate and predict the operation status of the entire water supply system, and is of great significance for the interconnected water supply, collaborative prevention and control, and water quality safety guarantee in water network construction. To address current issues, a 2D river hydrodynamic and water quality model and a 1D water supply plant-network model are established based on OpenFOAM. The embodiment of the present invention integrates the EPANET-MSX code to simulate complex biochemical reactions in the water supply plant-network, and builds a data exchange interface to update the inlet boundary conditions of the water treatment plant according to the water quality changes at the river water intake. The water treatment plant is simplified as a special treatment node in the pipeline system to relatively truly predict the hydraulic and water quality changes in the urban water supply pipe network, providing technical support for the prediction of sufficient drinking water supply and water quality guarantee.

As an alternative embodiment, for the simulation of river hydrodynamics and water quality, other software such as HEC-RAS, MIKE, and EFDC can also be used; for the simulation of hydrodynamics and water quality in water supply pipe networks, other software such as EPANET can also be used.

Specific Embodiments of the Present Invention are Further Described Below

An integrated hydrodynamic and water quality simulation method for water supply systems of water treatment plants, pipe networks, and rivers includes the following steps:
(1) First, it is necessary to obtain the river shoreline, topography of the target calculation area, as well as water level, flow rate, and water quality monitoring data at the boundaries. These data serve as the pre-requisite input conditions for the simulation of river hydrodynamics and water quality using OpenFOAM.
(2) For the simulation of hydrodynamics and water quality of the source water river: A model is constructed based on the open-source CFD software OpenFOAM. The Probe function in OpenFOAM's built-in postProcessing library is used to obtain and analyze the water quality changes at the water intake.
(3) Development of a data transmission interface from OpenFOAM to EPANET-MSX based on the Linux system: This interface enables one-way data transmission between OpenFOAM and EPANET-MSX (since there is no backflow of water from the water treatment plant to the river during the water supply process). The output file format of OpenFOAM is CSV, while the input file formats of EPANET-MSX are INP and MSX.
(4) Design of attribute fields for pipeline segments, nodes, and reservoir layers essential for the water supply pipe network: The attribute fields are reasonably designed to meet the requirements of establishing a hydrodynamic and water quality model for the water supply pipe network and conducting numerical calculations. Regarding the implementation of the water treatment plant, in the present invention, the water treatment plant is regarded as a special node for chlorination operations, and the removal efficiency of targeted pollutants is subject to a special reduction. The reduction rate can either be set manually or determined through a calibration method. Finally, EPANET-MSX is used to establish a hydrodynamic and water quality model for the water supply plant-network system.
(5) Writing a Python script: The script enables one-click execution of OpenFOAM, the data transmission interface, and EPANET-MSX on the Linux system, and automatically outputs the time-series curve graphs of water quality parameters for the required nodes or pipeline segments.

The specific process of step (2) includes:

Use CAD software to create a geometric model of the river shoreline and export it in a format recognizable by the mesh generation software ICEM (e.g., SAT or IGS). According to the complexity of the river, use ICEM to generate a 2D structured or unstructured mesh, export the mesh in Fluent format, and then convert it to a mesh format recognizable by OpenFOAM using the FluentMeshToFoam command. Save the converted mesh to the ‘PolyMesh’ folder under the case directory. It should be noted that OpenFOAM meshes are in a 3D format. For 2D simulations, the upper and lower boundaries are set to the “empty” type, and the vertical height is set to 1 (typically ranging from −0.5 to 0.5). After generating the shoreline mesh, it is necessary to interpolate the river topographic data onto the mesh. In OpenFOAM, the calculation results of variables (such as flow velocity, water level, and concentration) are stored at the centers of mesh cells, and topographic data is also stored at cell centers. Therefore, the coordinates of the mesh cell centers must first be obtained. This can be achieved by using the code ‘postProcess-time 0-func writeCellCentres’, which outputs the results to the ‘Cx’, ‘Cy’, and ‘Cz’ files in the “0 ” folder (corresponding to time step 0). Once the coordinates of the mesh cell centers are obtained, import the topographic data and mesh data into Tecplot. Use the “Interpolate” command to interpolate and obtain the topographic depth at the mesh cell centers (with the downward direction defined as positive). Export the interpolated topographic data using the “Write Data File” command, and copy this data into the ‘depth’ file in OpenFOAM. Subsequently, define the control parameters, initial conditions, and boundary conditions for OpenFOAM operation, including time step, total simulation duration, physical model settings, flow velocity, pressure, and concentration conditions at the river inlet and outlet, as well as the diffusion and attenuation coefficients of pollutants. Finally, utilize the Probe function in OpenFOAM's built-in postProcessing library: Create a ‘probes’ file in the ‘system’ folder of the OpenFOAM case to analyze the temporal variation of water quality parameters at specific coordinates (i.e., the water intake).

The specific process of step (3) includes:

First, specify the storage path of the CSV file that records the temporal variation of water quality parameters at the water intake (exported by the Probe function in OpenFOAM). Next, write a Python function to read the file data from OpenFOAM. This file mainly contains two columns: one for time and the other for water quality concentration. Convert the concentration values into relative coefficients by dividing each value in the concentration column by the first value in that column. Then, specify the storage path of the EPANET-MSX input file ‘example1.msx’. Use Python code to automatically update and input the calculated relative coefficients into the “PATTERNS” section of ‘example1.msx’, replacing the original time pattern. Here, “PATTERNS” refers to the time pattern used to define the time-varying intensity of external sources, and its format includes a pattern name and a series of relative coefficients of reference values. Ultimately, a communication bridge between OpenFOAM, Python, and EPANET-MSX is established.

The specific process of step (4) includes:

First, it is necessary to collect data such as the topology of the pipe network, pipe segment characteristics, node characteristics, and boundary conditions. It is required to establish point objects and line objects: the point objects include nodes, reservoirs, water tanks, etc.; the line objects include pipe segments, valves, pumps, etc. Attribute fields for nodes: Node number, X-coordinate, Y-coordinate, elevation, water demand, pattern; Attribute fields for reservoirs: Reservoir number, X-coordinate, Y-coordinate, total head, pattern; Attribute fields for water tanks: Water tank identifier, X-coordinate, Y-coordinate, elevation, initial water level, minimum water level, maximum water level, diameter, minimum volume, volume curve; Attribute fields for pipe segments: Pipe segment number, start node, end node, length, diameter, roughness coefficient, loss coefficient, initial state; Attribute fields for valves: Valve number, start node, end node, diameter, type, setting, loss coefficient; Attribute fields for pumps: Pump number, start node, end node, pump curve.

After that, configure simulation parameters such as the simulation time step and total duration. At the same time, define the hydrodynamic conditions of the pipe network, including pressure, flow rate, and water head, and ensure that the hydrodynamic states of all nodes and pipe segments are set correctly. Corresponding chemical species and reactions should also be added according to the water quality components to be simulated, and their chemical properties and kinetic parameters should be set. Set the initial state of the pipe network, including the initial concentration of water quality components and flow velocity, to prepare for the simulation calculation of hydrodynamics and water quality. The implementation of the water treatment plant can be achieved by adding a Source module to the MSX input file, which is used to simulate the process of adding chlorine at a specific concentration in the water treatment plant.

The specific process of step (5) includes:

Create a Python script, use the ‘subprocess’ module to call the OpenFOAM solver, and it is necessary to specify the path and name of the OpenFOAM case. In the same script, run the Python data transmission interface and call the EPANET-MSX library in the same way. Subsequently, draw the required time-series curve graphs of water quality parameters based on the output file ‘example1.rpt’ of the EPANET-MSX code. This process involves parsing and extracting information about specific nodes and pipe segments, applying a time conversion function to convert time data into floating-point numbers in hours, then defining a plotting function, setting the image format, and generating the time-series curve graphs of water quality parameters for specific nodes and pipe segments. Finally, test and run the Python script on the Linux system to ensure that all functions work properly, realizing the integrated operation of hydrodynamic and water quality simulation calculations from the estuary river to the water supply plant-network system.

In the embodiment of the present invention, the result output files of OpenFOAM are a series of folders corresponding to different time steps, and each folder contains the specific values of different parameters at the current time. However, the input files (INP and MSX files) of EPANET-MSX have specific input format requirements, so direct data transmission between the two program codes is not possible. Considering that the water supply process is a one-way transportation process, Python is used to write a data transmission interface for the hydrodynamic and water quality data of the river and the water supply pipe network. In addition, a script is written to realize one-click operation of the three sets of program codes and automatic plotting of result curves for nodes and pipe segments. Eventually, an applicable and promotable integrated water quality simulation solution for the water supply system of water treatment plants, pipe networks, and rivers is formed. By using the data transmission interface between the open-source OpenFOAM code (based on the Linux system) and the open-source one-dimensional pipe network code EPANET-MSX, result curve graphs can be generated during operation.

The technical solution framework of the embodiment of the present invention is shown in FIG. 1.

### EXAMPLE

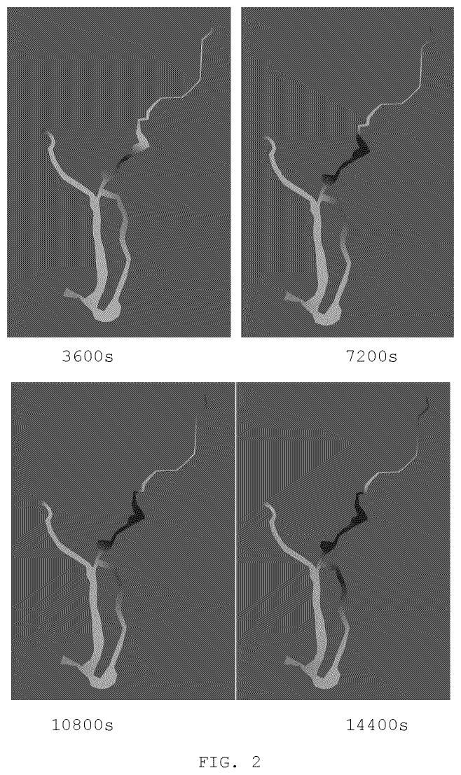

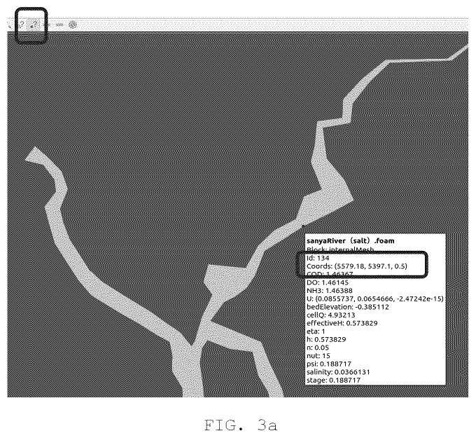

Due to the discharge of industrial wastewater and agricultural wastewater, trivalent arsenic (As³⁺) in the river undergoes advection and diffusion under hydraulic action, which further affects the water intake of the water treatment plant. After being treated by coagulation, sedimentation, and adsorption in the water treatment plant, As³⁺ enters the water supply pipe network, thereby affecting the oxidation and adsorption of arsenic in the pipe network and posing a potential threat to the safety of residents'drinking water. The simulation duration of this example is two days. This example demonstrates the applicability of the proposed method. FIG. 2 shows the spatiotemporal distribution of trivalent arsenic (As³⁺) in the river simulated by OpenFOAM. FIGS. 3a and 3b show the coordinates of the water intake and the extraction of time-series water quality data.

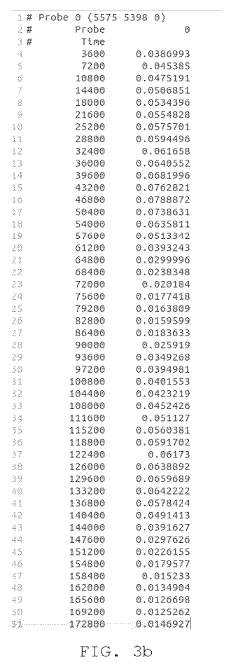

As shown in FIG. 4, for the construction of the water supply pipe network water quality model: the key focus is on the oxidation and adsorption reactions of trivalent arsenic (As³⁺) in the pipe network under the action of chloride ions, which involves the interaction process between the pipe wall and the flowing water source. In this process, since the water treatment plant mainly removes As³⁺ through coagulation, sedimentation, and adsorption, it is only necessary to apply a certain proportion of reduction to As³⁺ to reflect this treatment effect.

Finally, set the relevant operating parameters in accordance with the operation steps in the third part, and run the one-click Python code to complete the operation of the three programs and generate the graphs.

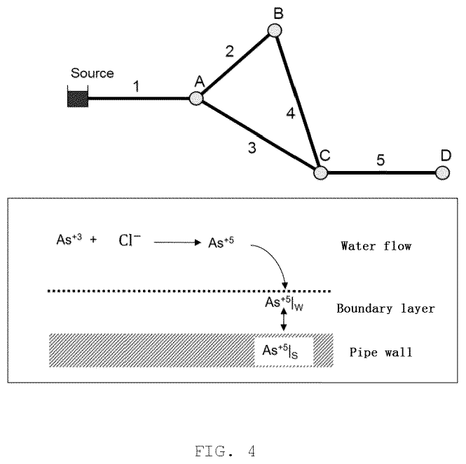

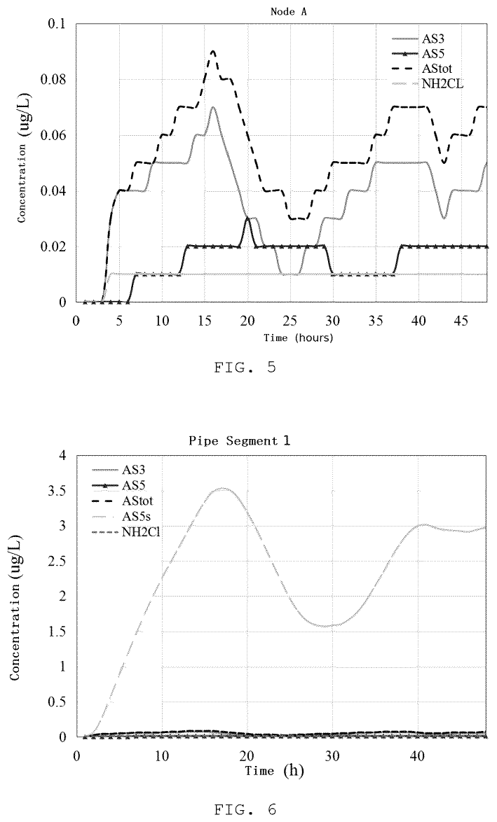

Taking Node A and Pipe Segment 1 as examples, the automatically generated time-series of water quality parameter changes are presented. FIG. 5 shows the variation trend of arsenic at Node A, and FIG. 6 shows the variation trend of arsenic in Pipe Segment 1.

Application Scenarios of the Present Invention Include the Following Aspects:

Water supply enterprises can adopt this method to establish an information management system for water supply pipe networks, conduct long-time-series water supply quality prediction and simulation, and use this system for the daily management and maintenance of pipe networks. This provides a basis for enhanced disinfection of water supply quality and energy conservation and consumption reduction in water supply systems. Water conservancy departments can use this method to conduct research on water quality stability guarantee measures for water supply under extreme disasters, and formulate water quality maintenance plans in response to impacts such as the deterioration of intake water quality. Through the integrated water supply quality prediction model of water treatment plants, pipe networks, and rivers constructed in the present invention, time-series graphs of water quality parameters for specified nodes and pipe segments (caused by changes in external water quality) can be automatically generated through operation. The method is simple to operate and easy to implement, enabling the prediction and simulation of water quality throughout the entire water intake process.

In Summary, the integrated water quality simulation method for water supply systems of water treatment plants, pipe networks, and rivers of the present invention can comprehensively evaluate and predict the operation status of the entire water supply system (from the water intake river and water treatment plant to the water supply pipe network) by constructing a water quality simulation model. By establishing a two-dimensional (2D) river hydrodynamic and water quality model and a one-dimensional (1D) water supply plant-network model, and constructing a data interface to realize data exchange and synchronization between the 2D river model and the water supply pipe network prediction model, complex biochemical reactions in the water supply plant-network can be simulated. The data exchange interface enables real-time updates of the inlet boundary conditions of the water treatment plant, and the water treatment plant is simplified as a treatment node in the pipeline system to truly reflect the hydraulic and water quality changes in the water supply pipe network. By integrating the river hydrodynamic and water quality model with the water supply pipe network prediction model into a complete numerical model for the integrated water supply system, the entire simulation process can be automated through one-click operation of the automated script and automatic plotting of result curves, forming a water quality simulation solution that is easy to apply and promote. The present invention is easy to implement, can automatically generate time-series graphs of water quality parameters, simplifies the operation process, and improves implementation efficiency. It is of great significance for the interconnected water supply, collaborative prevention and control, and water quality safety guarantee in water network construction. Water supply enterprises and water conservancy departments can use the present invention to establish an information management system for water supply pipe networks, conduct long-time-series water supply quality prediction and simulation, and provide a scientific basis for the daily management and maintenance of pipe networks, enhanced disinfection of water quality, energy conservation and consumption reduction, and research on water quality stability guarantee measures under extreme disasters.

Embodiments of the present invention further provide a storage medium. The storage medium is used for storing a computer program, and when the computer program is executed, it implements at least the method described above.

Embodiments of the present invention further provide a control device. The control device includes a processor and a storage medium for storing a computer program; wherein, when the processor executes the computer program, it implements at least the method described above.

Embodiments of the present invention further provide a processor. When the processor executes a computer program, it implements at least the method described above.

The storage medium may be implemented by any type of non-volatile storage device or a combination thereof. The non-volatile memory may be Read-Only Memory (ROM), Programmable Read-Only Memory (PROM), Erasable Programmable Read-Only Memory (EPROM), Electrically Erasable Programmable Read-Only Memory (EEPROM), Ferromagnetic Random Access Memory (FRAM), Flash Memory, magnetic surface memory, optical disc, or Compact Disc Read-Only Memory (CD-ROM); the magnetic surface memory may be a magnetic disk memory or a magnetic tape memory. The storage medium described in the embodiments of the present invention is intended to include, but is not limited to, these and any other suitable types of memory.

In the several embodiments provided by the present invention, it should be understood that the disclosed system and method may be implemented in other ways. The device embodiments described above are merely illustrative. For example, the division of the units is only a logical function division; in actual implementation, there may be other division methods (e.g., multiple units or components may be combined, integrated into another system, or some features may be omitted or not implemented). In addition, the coupling, direct coupling, or communication connection between the components shown or discussed may be implemented through some interfaces, and the indirect coupling or communication connection between devices or units may be electrical, mechanical, or in other forms.

The units described as separate components may or may not be physically separate; the components shown as units may or may not be physical units, i.e., they may be located in one place, or distributed across multiple network units. Some or all of the units may be selected according to actual needs to achieve the purpose of the solution of this embodiment.

In addition, all functional units in each embodiment of the present invention may be integrated into one processing unit, or each unit may exist alone as a separate unit, or two or more units may be integrated into one unit. The above-mentioned integrated units may be implemented in the form of hardware, or in the form of a combination of hardware and software functional units.

A person of ordinary skill in the art can understand that: to implement all or part of the steps of the above method embodiments, relevant hardware can be instructed by a program; the program can be stored in a computer-readable storage medium; when the program is executed, it performs the steps including the above method embodiments; and the aforementioned storage medium includes various media that can store program codes, such as a mobile storage device, ROM, Random Access Memory (RAM), magnetic disk, or optical disc.

Alternatively, if the integrated units in the present invention are implemented in the form of software functional modules and sold or used as independent products, they may also be stored in a computer-readable storage medium. Based on this understanding, the essence of the technical solution of the embodiments of the present invention, or the part that contributes to the prior art, can be embodied in the form of a software product. The computer software product is stored in a storage medium and includes several instructions for enabling a computer device (which may be a personal computer, a server, a network device, etc.) to execute all or part of the methods described in the various embodiments of the present invention. The aforementioned storage medium includes various media that can store program codes, such as a mobile storage device, ROM, RAM, magnetic disk, or optical disc.

The methods disclosed in the several method embodiments provided by the present invention can be combined arbitrarily without conflict to obtain new method embodiments.

The features disclosed in the several product embodiments provided by the present invention can be combined arbitrarily without conflict to obtain new product embodiments.

The features disclosed in the several method or device embodiments provided by the present invention can be combined arbitrarily without conflict to obtain new method embodiments or device embodiments.

The above content is a further detailed description of the present invention in conjunction with specific preferred implementations, and it cannot be considered that the specific implementation of the present invention is limited to these descriptions. For those skilled in the technical field to which the present invention belongs, without departing from the concept of the present invention, several equivalent substitutions or obvious modifications can also be made, and the performance or use is the same, which shall all be regarded as falling within the protection scope of the present invention.

The foregoing outlines the features of several embodiments, enabling those skilled in the art to fully appreciate the aspects of the present disclosure. Those skilled in the art should recognize that the present disclosure provides a foundation for designing or modifying other processes and structures to achieve substantially the same functions and/or substantially the same results as those of the embodiments introduced herein. Furthermore, such equivalent arrangements do not deviate from the spirit and scope of the present disclosure, and various changes, substitutions, and alterations may be made without so departing.

What is claimed is:

1. An integrated hydrodynamic and water quality simulation method for water supply systems of water treatment plants, pipe networks, and rivers, comprising the following steps:
S1: combining collected river topographic data and river shoreline data to construct a two-dimensional (2D) river hydrodynamic and water quality model, the model being configured with boundary hydrodynamic and water quality parameters to simulate the hydrodynamic and water quality conditions of the river water source;
S2: monitoring and analyzing the temporal variation of water quality parameters at the water intake by using the 2D river hydrodynamic and water quality model to provide key data for dynamic water quality assessment;
S3: constructing a water supply pipe network water quality prediction model that integrates multi-water source inputs, the water treatment plant being simplified as a treatment node in the pipeline system to simulate its water quality treatment effects;
S4: establishing a data interface to realize data exchange and synchronization between the 2D river hydrodynamic and water quality model and the water supply pipe network water quality prediction model;
S5: the water supply pipe network water quality prediction model performing one-dimensional (1D) hydrodynamic and water quality simulation of the water supply pipe network based on the data obtained from the 2D river hydrodynamic and water quality model, wherein the water quality and hydrodynamic parameters provided by the 2D river hydrodynamic and water quality model are input into the water supply pipe network water quality prediction model as boundary conditions or initial conditions to predict the water quality changes and hydraulic behaviors in the water supply pipe network;
S6: integrating the river hydrodynamic and water quality model and the water supply pipe network water quality prediction model into a complete numerical model for the integrated water supply system of water treatment plants, pipe networks, and rivers, to automate the entire water quality change simulation process.

2. The method according to claim 1, wherein in step S1, using OpenFOAM software to construct the 2D river hydrodynamic and water quality model; and in step S2, using the Probe function of OpenFOAM to monitor the changes of water quality parameters at the water intake and obtain the temporal variation data of the water quality parameters.

3. The method according to claim 2, wherein step S2 specifically comprises:
S2.1: establishing a geometric model of the river shoreline and exporting it in a format suitable for mesh generation software;
S2.2: using mesh generation software to draw a 2D mesh adapted to the river morphology according to the characteristics of the river and outputting it in a format suitable for the Computational Fluid Dynamics (CFD) software OpenFOAM;
S2.3: converting the exported mesh file into a format recognizable by OpenFOAM software and storing it as a standard mesh file in the case folder;
S2.4: setting the properties of the mesh in OpenFOAM software, and for 2D simulation, specifying the upper and lower boundary conditions and setting the dimension in the vertical direction;
S2.5: using the built-in tools of OpenFOAM software to extract the coordinate data of the mesh centers;
S2.6: performing topographic data interpolation by combining the topographic data with the mesh data, using interpolation technology to obtain the topographic depth information at the mesh centers and exporting the data;
S2.7: integrating the interpolated topographic data into the model of OpenFOAM software to provide accurate topographic conditions for the simulation;
S2.8: defining model parameters by setting the simulation parameters of OpenFOAM software, including time step, total simulation time, physical model settings, boundary conditions, and the diffusion and attenuation characteristics of pollutants;
S2.9: setting monitoring points in OpenFOAM software to track and record the temporal changes of water quality parameters at specific locations.

4. The method according to claim 2, wherein in step S3, using EPANET-MSX software to establish the water supply pipe network water quality prediction model based on the collected data of pipe network topology, pipe segment characteristics, node characteristics and boundary conditions.

5. The method according to claim 4, wherein step S3 specifically comprises:
S3.1: collecting data such as the topology of the water supply pipe network, pipe segment characteristics, node characteristics and boundary conditions;
S3.2: creating point objects and line objects in the water supply pipe network, the point objects including nodes, reservoirs and water tanks, and the line objects including pipe segments, valves and pumps;
S3.3: defining attribute fields for the point objects and line objects respectively;
S3.4: setting simulation parameters to provide time control for the simulation process;
S3.5: defining the hydrodynamic conditions of the pipe network and setting the hydrodynamic states of all nodes and pipe segments;
S3.6: adding corresponding chemical species according to the simulation requirements and setting their chemical properties and kinetic parameters;
S3.7: configuring the initial state of water quality components in the pipe network;
S3.8: simulating the water treatment plant process by adding a Source module to the model.

6. The method according to claim 4, wherein in step S4, constructing a data interface by writing Python scripts to realize data exchange between OpenFOAM software and EPANET-MSX software and converting the water quality and hydrodynamic parameters output by OpenFOAM into the input format required by EPANET-MSX software.

7. The method according to claim 6, wherein step S4 specifically comprises:
S4.1: determining the storage path of the CSV file recording the temporal variation of water quality parameters at the water intake, the CSV file being exported by the probe function of OpenFOAM software;
S4.2: developing a Python function to read water quality parameter data from OpenFOAM software, the water quality parameter data including water quality concentration data;
S4.3: converting the read water quality concentration data into relative coefficients and realizing standardization by dividing each value in the concentration column by the first value of the column;
S4.4: determining the storage path of the input file of EPANET-MSX software;
S4.5: using Python code to automatically update the calculated relative coefficients to the PATTERNS section in the EPANET-MSX model file;
S4.6: replacing the original time pattern with the newly calculated relative coefficients in the EPANET-MSX model file to reflect the temporal variation of water quality parameters.

8. The method according to claim 4, wherein step S6 specifically comprises:
S6.1: creating a Python script, using the subprocess module in the Python script to specify the path and name of the OpenFOAM case and call the OpenFOAM solver to run the simulation;
S6.2: running the Python data transmission interface through the Python script to realize data synchronization between different software;
S6.3: calling the EPANET-MSX library through the Python script to execute the water quality simulation of the water supply pipe network;
S6.4: parsing the water quality parameter information of specific nodes and pipe segments from the output file of EPANET-MSX;
S6.6: converting the parsed time data into floating-point numbers in hours to meet the plotting requirements;
S6.7: defining a plotting function in Python, setting the image format to prepare for generating the time-series curve graph;
S6.8: using the defined plotting function to generate the time-series curve graph of water quality parameters for specific nodes and pipe segments.

9. A computer-readable storage medium storing a computer program, wherein when the computer program is executed by a processor, it implements the integrated hydrodynamic and water quality simulation method for water supply systems of water treatment plants, pipe networks, and rivers according to claim 1.

10. A computer program product including a computer program, wherein when the computer program is executed by a processor, it implements the integrated hydrodynamic and water quality simulation method for water supply systems of water treatment plants, pipe networks, and rivers according to claim 1.
